(19) United States
(12) Patent Application Publication
(10) Pub. No.: US 2026/0271303 A1
(43) Pub. Date: Sep. 10, 2026

(54) SKYRMION MEMORY DEVICE AND CROSSBAR ARRAY CIRCUIT USING SAME

(71) Applicants: ICUF-HYU (INDUSTRY-UNIVERSITY COOPERATION FOUNDATION HANYANG UNIVERSITY), Seoul (KR); KOREA RESEARCH INSTITUTE OF STANDDARDS AND SCIENCE, Daejeon (KR)

(72) Inventors: Jea Gun PARK, Seongnam-si (KR); Jin Young CHOI, Seoul (KR); Han Sol JUN, Seoul (KR); Yo Han CHOI, Seoul (KR); Chan Yong HWANG, Seoul (KR); Seung Mo YANG, Daejeon (KR); Kyoung-Woong MOON, Daejeon (KR)

(73) Assignees: ICUF-HYU (INDUSTRY-UNIVERSITY COOPERATION FOUNDATION HANYANG UNIVERSITY), Seoul (KR); KOREA RESEARCH INSTITUTE OF STANDDARDS AND SCIENCE, Daejeon (KR)

(21) Appl. No.: 19/167,536

(22) PCT Filed: Mar. 21, 2024
(86) PCT No.: PCT/KR2024/095621

§ 371 Date: Sep. 22, 2025

(30) Foreign Application Priority Data
Mar. 21, 2023 (KR) 10-2023-0036282

(51) Int. Cl. H10B 61/00; H10N 50/10; H10N 50/85

(52) U.S. Cl. CPC H10B 61/10; H10N 50/10; H10N 50/85

(57) ABSTRACT

The present invention relates to a skyrmion memory device and a crossbar array circuit using the same. More particularly, a skyrmion memory device according to an embodiment of the present invention includes a microelectrode for generating one or more skyrmions; and a magnetic tunnel junction for controlling and detecting a size and number of the generated skyrmions, wherein the magnetic tunnel junction includes a seed layer, a synthetic anti-ferromagnetic layer, a bridge layer, a pinned layer, a tunnel barrier layer, an insertion layer, and a free layer, the microelectrode generates the skyrmions in the free layer when a voltage pulse is applied through a bottom electrode and a top electrode, and the size and number of the generated skyrmions are controlled based on at least one of a magnitude of the voltage pulse, a thickness of the insertion layer, and a type of material forming the insertion layer.

### TECHNICAL FIELD

The present invention relates to a skyrmion memory device and a crossbar array circuit using the same, and more particularly to a technology for implementing a skyrmion memory device and a crossbar array circuit using the same, wherein the device is composed of a microelectrode for generating skyrmions and a magnetic tunnel junction for controlling and detecting the size and number of the skyrmions, thereby exhibiting a linear change in resistance corresponding to the number of skyrmions.

### BACKGROUND ART

To implement an artificial intelligence semiconductor chip, a highly integrated cross-point synapse crossbar array circuit and neuron are required.

In the related art, CMOS FET cross-point arrays and next-generation memory (RRAM, PCRAM, STT-MRAM, SOT-MRAM)-based cross-point arrays have been reported. However, they have a drawback in that linearity during potentiation and depression is poor, thereby requiring additional compensation circuits.

In 2020, a research team at the Massachusetts Institute of Technology (MIT) in the United States reported an artificial synapse device implemented by domain wall motion based on a spin-orbit torque (SOT) channel (Marc A. Baldo et al., Magnetic Domain Wall Based Synaptic and Activation Function Generator for Neuromorphic Accelerators, Nano Lett., 1033-1040, 2020).

The artificial synapse device reported by MIT is configured with a Ta SOT channel, a free layer (information storage layer), a tunnel barrier layer, a pinned layer (magnetic layer), a connection layer, lower synthetic anti-ferromagnetic multi-layers (SyAF MLs), a spacing layer, upper synthetic anti-ferromagnetic multi-layer (SyAF MLs), a capping layer, and an upper electrode.

In existing artificial synapse devices, domain wall motion in the free layer is induced by the SOT effect generated in a Ta SOT channel, thereby switching the spin direction of the free layer of a pSTT-MRAM for sensing, resulting in a resistance change and, thus, the implementation of potentiation and depression operations of synapses

However, since the SOT channel and the pSTT-MRAM are arranged in a lateral structure, the minimum feature size is 93F², which presents a critical drawback in terms of integration density.

In other words, the SOT-MRAM-based synapse device structure in the related art has a three-terminal structure that cannot be highly integrated, and the SOT-MRAM-based synapse device has the problems that a large amount of energy is required due to domain wall motion and that it is affected by pinning caused by defect sites.

In addition, as a 3-terminal device with separate read/write paths, it requires additional wiring, which presents the disadvantage of increasing process complexity.

Furthermore, as a 3-terminal device with separate read/write paths, a 1R2T (one resistor, two transistors) structure, instead of a 1R1T structure, is required to read from and write to the device. This complicates the process and presents the disadvantage of requiring more energy for the device's read/write operations.

### DISCLOSURE

### Technical Problem

Therefore, the present invention has been made in view of the above problems, and it is one object of the present invention to implement a skyrmion memory device and a crossbar array circuit using the same, the skyrmion memory device being composed of a microelectrode for generating skyrmions; and a magnetic tunnel junction for controlling and detecting the size and number of the skyrmions, so that a change in resistance according to the number of skyrmions is linear.

It is another object of the present invention to implement a skyrmion memory device as a double free p-MTJ spin-valve that is lower-cost, higher-density, and lower-power than existing structures. This is achieved by providing a skyrmion channel and a magnetic tunnel junction where skyrmions are stably formed in a free layer by using an insertion layer.

It is still another object of the present invention to provide a skyrmion memory device and a crossbar array circuit using the same that can linearly achieve potentiation and depression. This is accomplished by a structure wherein an insertion layer is added at the interface of the free layer and the tunneling barrier to form a stable skyrmion channel, and skyrmions are generated by an input pulse through a microelectrode including electrochemical metallization memory (ECM), valence change memory (VCM), or a mixture thereof, to change the free layer of the magnetic tunnel junction, thereby causing resistance to vary according to the number of skyrmions.

It is still another object of the present invention to implement an ultra-low-power synaptic device based on a skyrmion memory device with a linear resistance change according to the number of skyrmions. In this device, the voltage to generate skyrmions is very low (1 V or less), and the voltage to sense the skyrmions via the magnetic tunnel junction is also very low (approximately 0.1 V).

It is still another object of the present invention to improve the computational accuracy of machine learning by linearly controlling the potentiation and depression of the synaptic device through the control of the generation and annihilation of skyrmions.

It is still another object of the present invention to provide a skyrmion memory device that can be used as a magnetic non-volatile memory capable of high-speed rewriting, a neuromorphic computing device, a neuromorphic device, and artificial intelligence hardware.

It is yet another object of the present invention to secure high reliability through high current density transfer via a filament by using a microelectrode including ECM, VCM, or a mixture thereof.

### Technical Solution

In accordance with an aspect of the present invention, the above and other objects can be accomplished by the provision of a skyrmion memory device, including: a microelectrode for generating one or more skyrmions; and a magnetic tunnel junction for controlling and detecting a size and number of the generated skyrmions, wherein the magnetic tunnel junction includes a seed layer, a synthetic anti-ferromagnetic layer, a bridge layer, a pinned layer, a tunnel barrier layer, an insertion layer, and a free layer, the microelectrode generates the skyrmions in the free layer when a voltage pulse is applied through a bottom electrode and a top electrode, and the size and number of the generated skyrmions are controlled based on at least one of a magnitude of the voltage pulse, a thickness of the insertion layer, and a type of material forming the insertion layer.

The magnetic tunnel junction may control a resistance level in a multi-level manner as the Dzyaloshinskii-Moriya Interaction (DMI) and Perpendicular Magnetic Anisotropy (PMA) of the free layer are controlled based on the thickness of the insertion layer, thereby controlling the size and number of the skyrmions.

The magnetic tunnel junction may detect multi-bit skyrmions when a plurality of skyrmions are present, and the area of the free layer may increase according to the multi-bit skyrmions.

The magnetic tunnel junction may secure linearity of potentiation and depression implemented in a multi-level manner as the area of the free layer increases and, accordingly, a resistance level gradually changes.

The insertion layer may be formed of one of Ta, W, Pt, Mo, and Ti, and the thickness of the insertion layer may be inversely proportional to the size and number of the generated skyrmions.

The microelectrode may be one of an electrochemical metallization memory (ECM) electrode, a valence change memory (VCM) electrode, and a combined ECM and VCM electrode, and may be configured to control a density of current applied to the free layer.

The microelectrode may include a metal electrode and a resistive switching layer, the resistive switching layer may be formed of one of SiOx, MgO, HfOx, AlOx, TiOx, TaOx, GeSe, GeS2, GeTe, and ZnTe, and the metal electrode may be formed of one of Al, TiN, Ti, W, Cu, CuTe, Pt, Ag, and Ru.

The magnetic tunnel junction may include an additional tunnel barrier layer between the microelectrode and the free layer, and include an additional free layer between the insertion layer and the tunnel barrier layer, thereby including a double free layer in which the skyrmions are generated.

According to an embodiment of the present invention, the skyrmion memory device may further include the bottom electrode located below the magnetic tunnel junction; and the top electrode located on the microelectrode.

It is another object of the present invention to provide a crossbar array circuit using a skyrmion memory device, the skyrmion memory device including a top electrode, a bottom electrode, a microelectrode for generating one or more skyrmions, and a magnetic tunnel junction for controlling and detecting a size and number of the generated skyrmions, wherein the magnetic tunnel junction includes a seed layer, a synthetic anti-ferromagnetic layer, a bridge layer, a pinned layer, a tunnel barrier layer, an insertion layer, and a free layer, wherein the microelectrode generates the skyrmions in the free layer when a voltage pulse is applied to the bottom electrode and the top electrode, and the magnetic tunnel junction controls a size and number of the generated skyrmions based on at least one of a magnitude of the voltage pulse, a thickness of the insertion layer, and a type of material forming the insertion layer, the circuit including: an array of a plurality of bit cells, wherein each of the bit cells is formed by connecting a first control signal line to the top electrode and a second control signal line to the bottom electrode of the skyrmion memory device; a selection driver for applying a selection control signal through one of the first control signal line and the second control signal line; and a read and write controller for applying read and write control signals through the other of the first control signal line and the second control signal line.

The bit cell may have a 2-terminal structure in which the first control signal line is connected to the top electrode and the second control signal line is connected to the bottom electrode.

### Advantageous Effects

According to an embodiment, the present invention can implement a skyrmion memory device and a crossbar array circuit using the same, the skyrmion memory device being composed of a microelectrode for generating skyrmions; and a magnetic tunnel junction for controlling and detecting the size and number of the skyrmions, so that a change in resistance according to the number of skyrmions is linear.

The present invention can implement a skyrmion memory device as a double free p-MTJ spin-valve that is lower-cost, higher-density, and lower-power than existing structures. This is achieved by providing a skyrmion channel and a magnetic tunnel junction where skyrmions are stably formed in a free layer by using an insertion layer.

The present invention can provide a skyrmion memory device and a crossbar array circuit using the same that can linearly achieve potentiation and depression. This is accomplished by a structure wherein an insertion layer is added at the interface of the free layer and the tunneling barrier to form a stable skyrmion channel, and skyrmions are generated by an input pulse through a microelectrode including electrochemical metallization memory (ECM), valence change memory (VCM), or a mixture thereof, to change the free layer of the magnetic tunnel junction, thereby causing resistance to vary according to the number of skyrmions.

The present invention can improve the computational accuracy of machine learning by linearly controlling the potentiation and depression of the synaptic device through the control of skyrmion generation and annihilation.

The present invention can implement an ultra-low-power synaptic device based on a skyrmion memory device with a linear resistance change according to the number of skyrmions. In this device, the voltage to generate skyrmions is very low (1 V or less), and the voltage to sense the skyrmions via the magnetic tunnel junction is also very low (approximately 0.1 V).

The present invention can provide a skyrmion memory device that can be used as a magnetic non-volatile memory capable of high-speed rewriting, a neuromorphic computing device, a neuromorphic device, and artificial intelligence hardware.

The present invention can secure high reliability through high current density transfer via a filament by using a microelectrode including ECM, VCM, or a mixture thereof.

### DESCRIPTION OF DRAWINGS

FIGS. 1 and 2 are diagrams illustrating a skyrmion memory device according to an embodiment of the present invention.

FIG. 3 is a diagram for explaining a crossbar array circuit using the skyrmion memory device according to an embodiment of the present invention.

FIG. 4 is a diagram for explaining the correlation between an insertion layer in the skyrmion memory device according to an embodiment of the present invention and the size of skyrmions.

FIGS. 5a to 5e are diagrams for explaining the multi-level implementation of the skyrmion memory device according to an embodiment of the present invention.

FIG. 6 is a diagram for explaining skyrmion generation and the control of the number of skyrmions, based on a microelectrode of the skyrmion memory device according to an embodiment of the present invention.

FIGS. 7 to 9c are diagrams for explaining the characteristics of the microelectrode of the skyrmion memory device according to an embodiment of the present invention.

### BEST MODE

The embodiments will be described in detail herein with reference to the drawings.

The embodiments and the terms used herein are not intended to limit the disclosed technology to specific implementations described in this document, but should be understood to include various modifications, equivalents, and/or alternatives thereof.

In the following description of the present invention, a detailed description of known functions and configurations incorporated herein will be omitted when it may make the subject matter of the present invention unclear.

The terms used in the specification are defined in consideration of functions used in the present invention, and can be changed according to the intent or conventional used methods of clients, operators, and users. Accordingly, definitions of the terms should be understood on the basis of the entire description of the present specification.

In description of the drawings, like reference numerals may be used for similar elements.

The singular expressions in the present specification may encompass plural expressions unless clearly specified otherwise in context.

In this specification, expressions such as “A or B” and “at least one of A and/or B” may include all possible combinations of the items listed together.

Expressions such as “first” and “second” may be used to qualify the elements irrespective of order or importance, and are used to distinguish one element from another and do not limit the elements.

It will be understood that when an element (e.g., first) is referred to as being “connected to” or “coupled to” another element (e.g., second), it may be directly connected or coupled to the other element or an intervening element (e.g., third) may be present.

As used herein, “configured to” may be used interchangeably with, for example, “suitable for”, “ability to”, “changed to”, “made to”, “capable of”, or “designed to” in terms of hardware or software.

In some situations, the expression “device configured to” may mean that the device “may do ~” with other devices or components.

For example, in the sentence “processor configured to perform A, B, and C”, the processor may refer to a general-purpose processor (e.g., CPU or application processor) capable of performing corresponding operation by running a dedicated processor (e.g., embedded processor) for performing the corresponding operation, or one or more software programs stored in a memory device.

In addition, the expression “or” means “inclusive or” rather than “exclusive or”.

That is, unless otherwise mentioned or clearly inferred from context, the expression “x uses a or b” means any one of natural inclusive permutations.

In the aforementioned embodiments, constituents of the present invention were expressed in a singular or plural form depending upon embodiments thereof.

However, the singular or plural expressions should be understood to be suitably selected depending upon a suggested situation for convenience of description, and the aforementioned embodiments should be understood not to be limited to the disclosed singular or plural forms. In other words, it should be understood that plural constituents may be a singular constituent or a singular constituent may be plural constituents.

While the embodiments of the present invention have been described, those skilled in the art will appreciate that many modifications and changes can be made to the present invention without departing from the spirit and essential characteristics of the present invention.

Therefore, it should be understood that there is no intent to limit the invention to the embodiments disclosed, rather, the invention is to cover all modifications, equivalents, and alternatives falling within the spirit and scope of the invention as defined by the claims.

Therefore, a microelectrode may increase a current density transferred to a free layer of a skyrmion memory device while simultaneously ensuring high reliability.

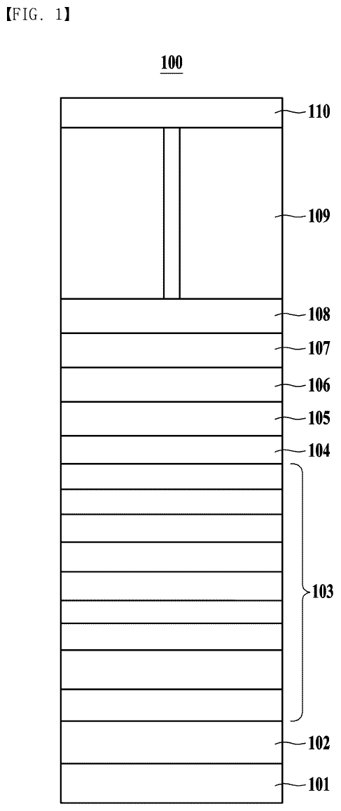

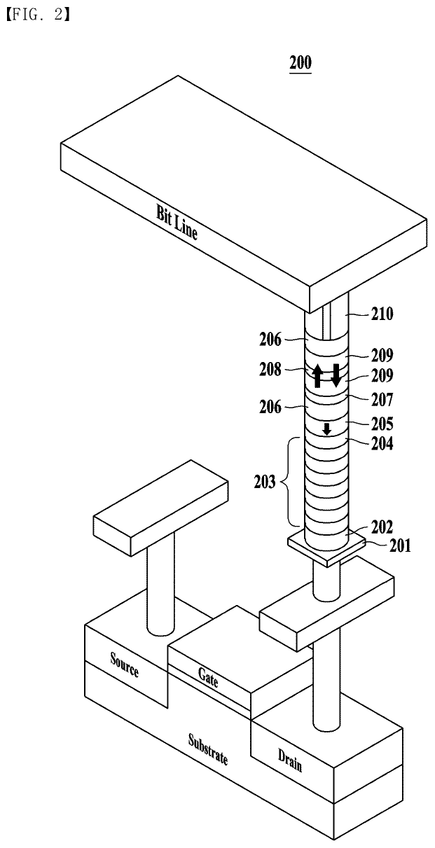

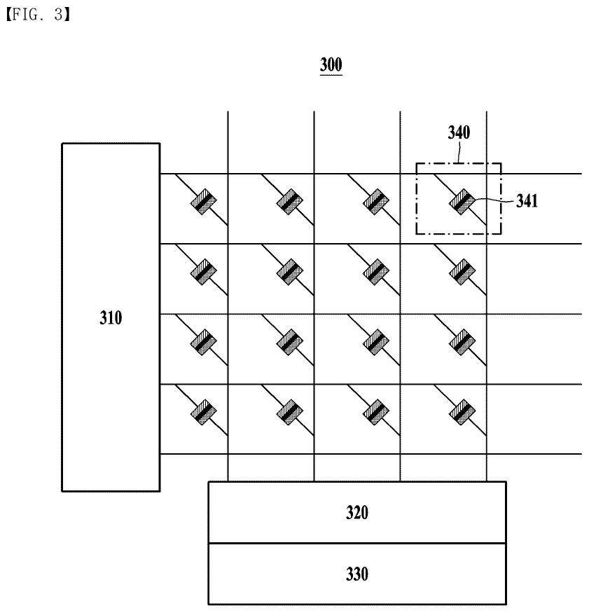

FIGS. 1 and 2 are diagrams illustrating a skyrmion memory device according to an embodiment of the present invention.

FIG. 1 illustrates the structure of the skyrmion memory device according to an embodiment of the present invention.

Referring to FIG. 1, the skyrmion memory device 100 is composed of a magnetic tunnel junction and a microelectrode 109.

The magnetic tunnel junction includes a seed layer 102, a synthetic anti-ferromagnetic multi-layer 103, a bridge layer 104, a pinned layer 105, a tunnel barrier layer 106, an insertion layer 107, and a free layer 108.

In addition, the skyrmion memory device 100 further includes a bottom electrode 101 located below the magnetic tunnel junction and a top electrode 110 located on the microelectrode 109.

For example, the microelectrode 109 may refer to a resistive switching vertical electrode that is composed of an electrode and a resistive switching layer, and that vertically generates a micro-filament on the resistive switching layer.

According to an embodiment of the present invention, the microelectrode 109 generates skyrmions in the free layer 108 when a voltage pulse is applied through the bottom electrode 101 and the top electrode 110.

The tunnel barrier layer 106, insertion layer 107, and free layer 108 of the magnetic tunnel junction may be a skyrmion channel layer, which is a path for skyrmion movement and generation.

The magnetic tunnel junction controls and detects the size and number of skyrmions generated through the microelectrode 109.

In the skyrmion memory device 100, since the thickness and forming-material type of the insertion layer 107 of the magnetic tunnel junction and the magnitude of the voltage pulse are controllable, the size and number of the generated skyrmions may be controlled based on at least one of the magnitude of the voltage pulse, the thickness of the insertion layer 107, and the type of material forming the insertion layer 107.

For example, the magnetic tunnel junction may control the resistance level in a multi-level manner as the Dzyaloshinskii-Moriya Interaction (DMI) and Perpendicular Magnetic Anisotropy (PMA) of the free layer 108 are controlled based on the thickness of the insertion layer 107, thereby controlling the size and number of the skyrmions.

According to an embodiment of the present invention, the magnetic tunnel junction may detect multi-bit skyrmions when there are a plurality of skyrmions, and the area of the free layer 108 may increase according to the multi-bit skyrmions.

Here, the increase in the area of the free layer 108 may mean an increase in the number of skyrmions on the free layer.

For example, the magnetic tunnel junction may secure the linearity of potentiation and depression, which are implemented in a multi-level manner, as the resistance level gradually changes with the increase in the area of the free layer 108.

According to an embodiment of the present invention, the insertion layer 107 is formed of one of Ta, W, Pt, Mo, and Ti, and the thickness of the insertion layer 107 may be inversely proportional to the size and number of the pre-generated skyrmions. That is, the insertion layer 107 may be formed of a non-magnetic metal (NM) material or the like.

The microelectrode may be one of an electrochemical metallization memory (ECM) electrode, a valence change memory (VCM) electrode, and a combined ECM and VCM electrode, to control the density of current applied to the free layer 108.

The combined ECM and VCM electrode is an electrode that combines the characteristics of ECM and VCM.

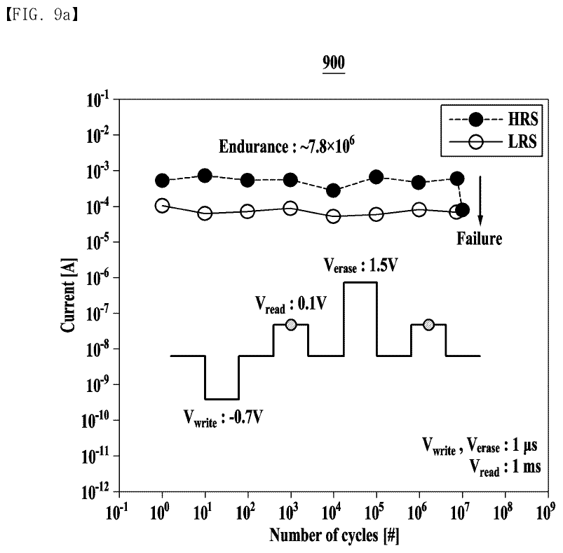

The characteristics of the ECM electrode, VCM electrode, and ECM+VCM electrode will be supplementarily explained with reference to FIGS. 7 to 9c.

According to an embodiment of the present invention, the microelectrode 109 includes a metal electrode and a resistive switching layer. Here, the resistive switching layer may be formed of one of SiOx, MgO, HfOx, AlOx, TiOx, TaOx, GeSe, GeS2, GeTe, and ZnTe, and the metal electrode may be formed of one of Al, TiN, Ti, W, Cu, CuTe, Pt, Ag, and Ru. In addition, the metal electrode may also be formed of a new NM material.

For example, the resistive switching layer may be formed of a binary oxide or a chalcogenide.

This patent relates to a technology necessary for the development of a skyrmion-based spin device, and furthermore, this memory can replace the basic 1T1C (1 transistor and 1 capacitor) cell unit of existing p-STT MRAM and DRAM with a 1T1R (1 transistor 1 magnetic tunneling junction) structure using a transistor and a skyrmion-based p-MTJ, thereby enabling a high-integration process and significantly solving the problems of integration density and power consumption compared to a basic cell, which requires 6-8 transistors, of an existing SRAM synaptic device.

Compared to a pSTT MRAM-based synaptic device, it enables complex ANN implementation due to multi-bit capability and can greatly reduce power consumption with a low operating current.

Additionally, by adding a non-volatile characteristic, it can serve as a non-volatile memory capable of high-speed rewriting, and can replace existing non-volatile SRAM synaptic devices and synaptic devices utilizing next-generation memory (ReRAM, PCRAM, MRAM).

In the skyrmion memory device 100, when current passes through the skyrmion-generating microelectrode 109, skyrmions are generated or annihilated at the interface of the free layer 108 of the magnetic tunnel junction due to the high current density.

At this time, in the skyrmion memory device 100, the area corresponding to the size of the skyrmion becomes anti-parallel to the magnetization direction of the pinned layer 105, so the resistance of the device changes according to the number of skyrmions.

In addition, in the skyrmion memory device 100, the resistance increases as the number of skyrmions at the interface of the free layer 108 increases, and the resistance decreases as the number of skyrmions decreases.

In addition, an increase in the number of skyrmions in the free layer 108 may be considered an increase in the area of the free layer 108.

For example, the skyrmion memory device 100 may be a synaptic device capable of potentiation and depression operations according to the number of skyrmions inside the free layer 108.

FIG. 2 illustrates the structure of a 2-terminal multi-bit skyrmion memory device as a skyrmion memory device according to an embodiment of the present invention.

Referring to FIG. 2, a skyrmion memory device 200 according to an embodiment of the present invention may include a bottom electrode 201, a seed layer 202, a synthetic anti-ferromagnetic layer 203, a bridge layer 204, a pinned layer 205, a tunnel barrier layer 206, an insertion layer 207, a free layer 209, a spacer layer 208, a free layer 209, a tunnel barrier layer 206, and a microelectrode 210, wherein a top electrode is located on the microelectrode, and a bit line signal may be applied.

For example, the bottom electrode 201 is connected to a drain terminal of a switching element, so the skyrmion memory device 200 forms a 2-terminal structure.

According to an embodiment of the present invention, in the skyrmion memory device 200, the seed layer 202, the synthetic anti-ferromagnetic multi-layer 203, the bridge layer 204, the pinned layer 205, the tunnel barrier layer 206, the insertion layer 207, the free layer 209, the spacer layer 208, the free layer 209, the tunnel barrier layer 206 form a magnetic tunnel junction, generates skyrmions based on the combination of the magnetic tunnel junction and the microelectrode 210, and controls and detects the size and number of the generated skyrmions.

In other words, the magnetic tunnel junction of the skyrmion memory device 200 includes an additional tunnel barrier layer 206 between the microelectrode 210 and the free layer 209, and includes an additional free layer 209 between the insertion layer 207 and the spacer layer 208, thereby including a double free layer in which skyrmions are generated.

For example, in the skyrmion memory device 200, the magnetic tunnel junction where skyrmions are generated, controlled, and detected, and the microelectrode 210 for generating skyrmions are vertically stacked at once, which can drastically reduce the process procedure.

In addition, since the skyrmion memory device 200 is a 2-terminal type device (4F2 to 6F2) that connects power only to the top and bottom electrodes for the skyrmion generation operation, a 3-D cross point or existing CMOS process is possible, enabling the implementation of a high-density device.

The skyrmion memory device 200 requires skyrmion size control for small and stable skyrmion generation, which is to satisfy the conditions of high DMI and low PMA.

To this end, the skyrmion memory device 200 may generate skyrmions by depositing an insertion layer 207 for skyrmion formation between the tunnel barrier 206 and the free layer 208 to a very thin thickness (1 nm or less) to increase DMI and decrease PMA.

In addition, by adjusting the thickness of the insertion layer 207, the skyrmion size may be adjusted, and multiple small skyrmions may exist inside the free layer 209.

At this time, the free layer has a magnetization state opposite to the pinned layer by the area where the skyrmions are generated, so the resistance of the device increases.

In addition, when passing through the pinhole electrode, a high current density is delivered to the magnetic material of the free layer, forming skyrmions without a separate external magnetic field.

Since the spin direction of the free layer 209 is switched by the portion where the skyrmion is formed, resulting in a high-resistance state, the resistance of the device increases linearly according to the number of generated skyrmions. This may correspond to the skyrmion memory device 200 performing a potentiation operation as a synaptic device.

In addition, in the skyrmion memory device 200, if an opposite current is applied, the skyrmions are annihilated, and the resistance of the device decreases linearly.

This may correspond to the skyrmion memory device 200 performing a depression operation as a synaptic device.

Accordingly, the skyrmion memory device 200 may implement a multi-level synaptic device with a single device because the resistance changes according to the number of skyrmions.

Therefore, the present invention may implement a skyrmion memory device as a low-cost, high-density, low-power memory device compared to conventional structures, the skyrmion memory device being a double free p-MTJ spin-valve having a skyrmion channel and magnetic tunnel junction where skyrmions are stably formed in a free layer using an insertion layer.

In addition, the present invention may provide a skyrmion memory device and a crossbar array circuit using the same that linearly achieve potentiation and depression, based on a structure in which an insertion layer is added at an interface between the free layer and a tunneling barrier to form a stable skyrmion channel, and skyrmions are formed by an input pulse through a microelectrode (including electrochemical metallization memory (ECM), valence change memory (VCM), or a mixture thereof) to change the free layer of the magnetic tunnel junction, whereby the resistance changes according to the number of skyrmions.

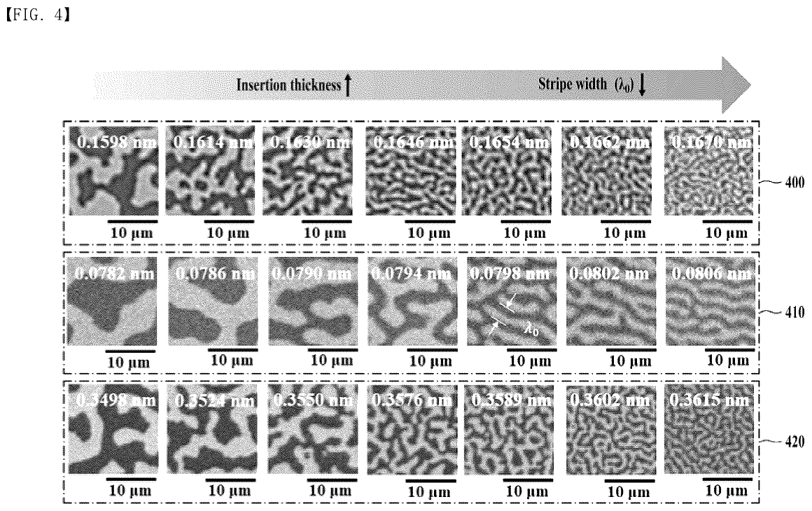

FIG. 3 is a diagram for explaining a crossbar array circuit using the skyrmion memory device according to an embodiment of the present invention.

According to an embodiment of the present invention, the skyrmion memory device may be implemented as a crossbar array circuit by being arranged to form a bit cell.

Referring to FIG. 3, a crossbar array circuit 300 includes a selection driver 310, a read controller 320, a write controller 330, and a plurality of bit cells 340.

For example, in a skyrmion memory device 341, a first control signal line is connected to a top electrode and a second control signal line is connected to a bottom electrode to form one bit cell 340, and a plurality of bit cells 340 are arranged.

For example, the selection driver 310 may apply a selection control signal through either the first control signal line or the second control signal line.

That is, the selection driver 310 applies a selection control signal through the control signal line to select one of the plural bit cells 340.

According to an embodiment of the present invention, the read controller 320 and the write controller 330 apply read and write control signals through the remaining control signal line among the first control signal line and the second control signal line.

Here, the remaining control signal line refers to the other control signal line other than the control signal line connected to the selection driver 310.

The read controller 320 and the write controller 330 apply read and write control signals through the control signal line to control the read and write operations for the selected bit cell.

According to an embodiment of the present invention, the skyrmion memory device may be controlled with two terminals in relation to the generation, annihilation, or reading of skyrmions, and when utilized as a synaptic device, this may provide the effect of controlling potentiation, depression, and reading with two terminals.

Therefore, the present invention may implement a skyrmion memory device and a crossbar array circuit using the same, the skyrmion memory device being configured with a microelectrode for generating skyrmions and a magnetic tunnel junction for detecting skyrmions while controlling the size and number of skyrmions such that resistance change according to the number of skyrmions is linear.

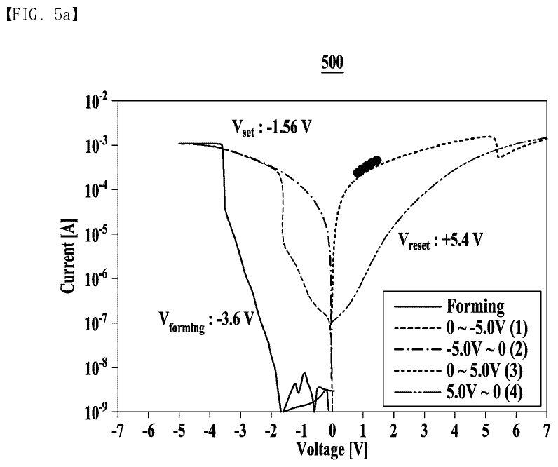

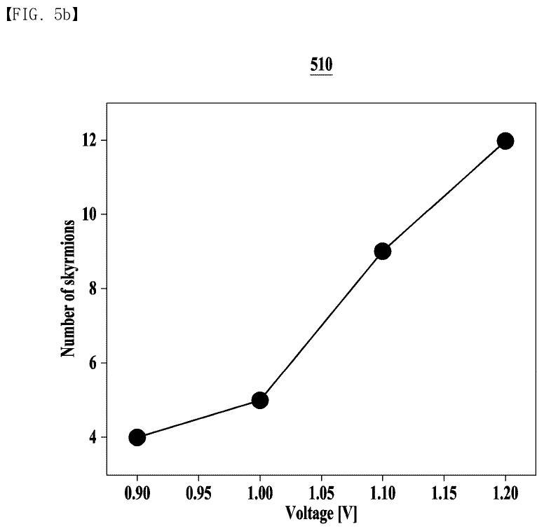

FIG. 4 is a diagram for explaining the correlation between the insertion layer in the skyrmion memory device according to an embodiment of the present invention and the size of skyrmions.

FIG. 4 illustrates Magneto-Optical Kerr Effect (MOKE) images according to the forming-material and thickness of the insertion layer in the skyrmion channel layer of the present invention.

Referring to FIG. 4, Image 400 shows the case where the insertion layer is formed of Pt, Image 410 shows the case where the insertion layer is formed of W, and Image 420 shows the case where the insertion layer is formed of Ti.

Since the stripe domain width (λ0) is proportional to

$$exp \sqrt{\frac{M \text{?} H \text{?}}{2}} ,$$

$$\text{?} \text{indicates text missing or illegible when filed}$$

can be confirmed that the stripe domain width decreases as the anisotropy field (HK) decreases, and about 1 μm of stripe width is secured at 0.1670 nm for Pt, 0.0806 nm for W, and 0.3615 nm for Ti.

In other words, according to Images 900 to 920, it can be confirmed that the stripe width decreases as the thickness of the insertion layer increases.

Since the stripe width is proportional to the size and number of skyrmions, it can be confirmed that the thickness of the insertion layer is inversely proportional to the size and number of skyrmions.

In other words, because the stripe domain and the size of skyrmions are in a proportional relationship, a decrease in the stripe domain thickness means a decrease in the skyrmion size.

Therefore, as the thickness of the insertion layer increases, DMI increases and PMA decreases, making it possible to generate small and stable skyrmions. Thus, by controlling the size of the synaptic device and the number of skyrmions, multi-level states may be adjusted, thereby freely tuning the specifications required by the system.

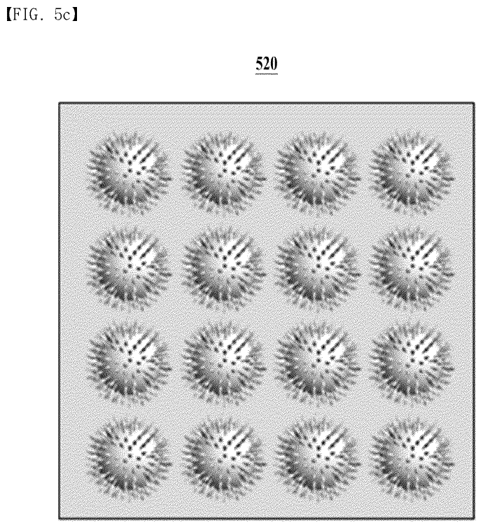

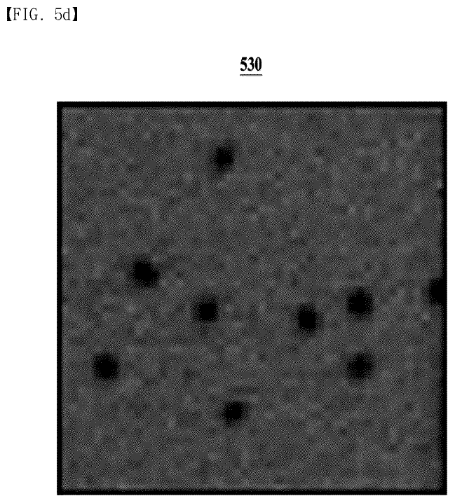

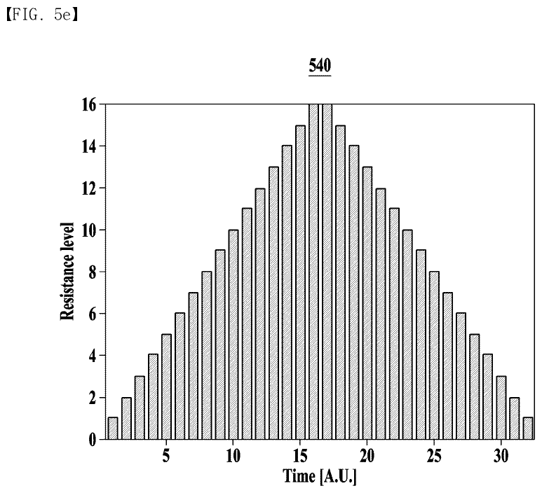

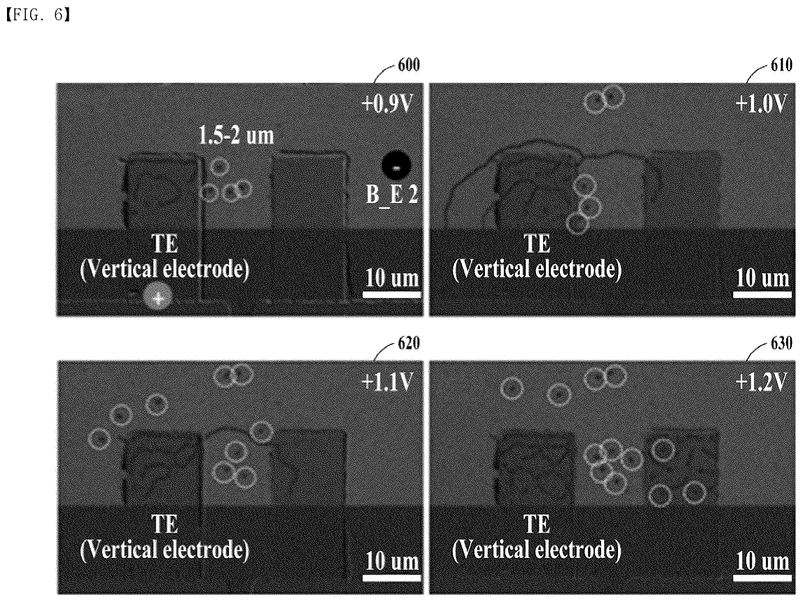

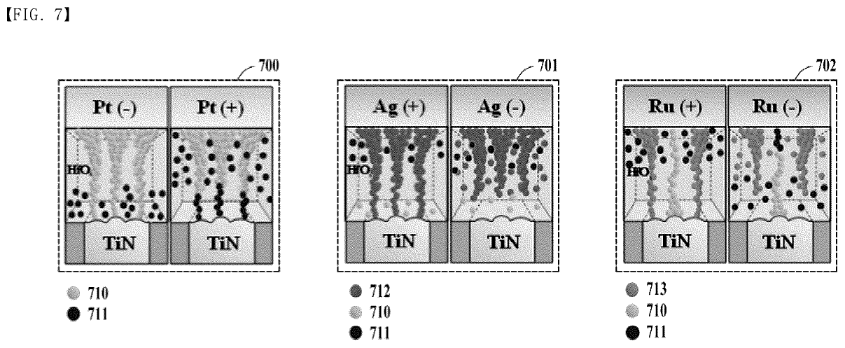

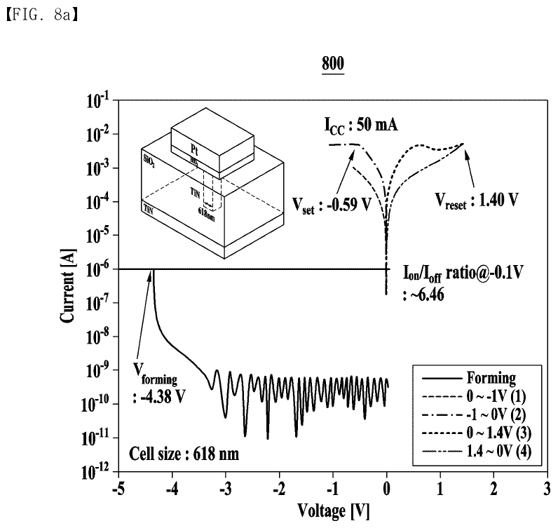

FIGS. 5a to 5e are diagrams for explaining the multi-level implementation of the skyrmion memory device according to an embodiment of the present invention.

FIG. 5a is a diagram for explaining an I-V curve in the structure of a microelectrode for skyrmion generation according to an embodiment of the present invention.

Graph 500 of FIG. 5a illustrates forming, set, and reset voltages through an I-V curve in a VCM electrode structure.

Referring to Graph 500, when the resistive switching layer of the VCM electrode composed of an electrode and a resistive switching layer has a thickness of 2 nm, the forming voltage is −3.6 V, the set voltage is −1.56 V, and the reset voltage is +5.4 V.

FIG. 5b illustrates the number of skyrmions generated depending on the magnitude of a voltage applied to the microelectrode of the skyrmion memory device through the top/bottom electrode according to an embodiment of the present invention.

Referring to FIG. 5b, Graph 510 shows that the number of skyrmions increases as the voltage increases.

The microelectrode for skyrmion generation supplies a high current density to the free layer when power is connected to the top/bottom electrode of the device.

In other words, in the skyrmion memory device, when a voltage pulse of 0.9 to 1.1 V for 200 ms is applied under conditions where a filament is formed by a set voltage, skyrmions are generated, and the number of skyrmions increases as the voltage magnitude increases. For example, about nine skyrmions may be generated at 1.1 V.

FIG. 5c illustrates 16-level multi-bit skyrmions according to an embodiment of the present invention, FIG. 5d illustrates MOKE images of multi-bit skyrmions, and FIG. 5e illustrates the potentiation and depression of 16-level multi-bit skyrmions as resistance levels according to an embodiment of the present invention.

Referring to FIG. 5c, Image 520 illustrates 16-level multi-bit skyrmions, Image 530 of FIG. 5d illustrates the MOKE image of about 16 multi-bit skyrmions, and Graph 540 of FIG. 5e illustrates the potentiation and depression of synapses according to the number of skyrmions.

When the number of skyrmions is fixed at 16 in the magnetic tunnel junction, the linear potentiation and depression of synapses may be implemented, illustrating that the device may also function as a synaptic device.

The magnetic tunnel junction of the skyrmion memory device according to an embodiment of the present invention may sense multi-bit skyrmions when the number of skyrmions is multiple, and as the area of the free layer increases according to the multi-bit skyrmions, resistance levels gradually change, thereby securing the linearity of potentiation and depression implemented as multi-levels.

Therefore, in the present invention, the insertion layer is located between the free layer and the tunnel barrier layer, and the size of skyrmions is controlled depending on the type and thickness of the material forming the insertion layer, thereby adjusting the number of skyrmions in a single magnetic tunnel junction to implement multi-level bits.

Accordingly, the present invention may control the generation and annihilation of skyrmions to linearly control the potentiation and depression of a synaptic device, thereby improving the computational accuracy of machine learning.

In addition, based on the skyrmion memory device in which resistance changes linearly according to the number of skyrmions, the voltage for generating skyrmions is very low at 1 V or less, and the voltage for detecting skyrmions moved through the magnetic tunnel junction is about 0.1 V, thereby enabling the implementation of an ultra-low-power synaptic device.

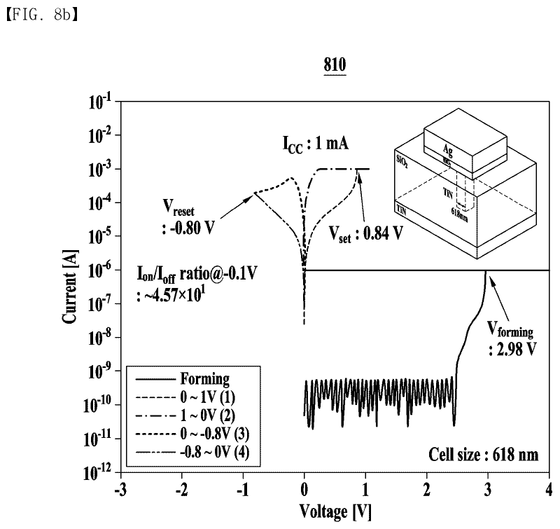

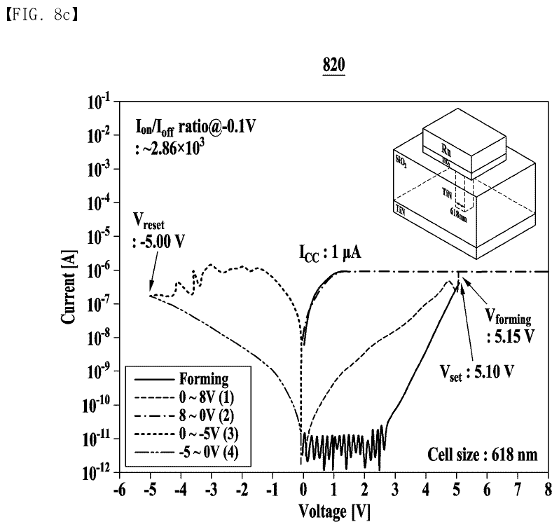

FIG. 6 is a diagram for explaining skyrmion generation and the control of the number of skyrmions, based on the microelectrode of the skyrmion memory device according to an embodiment of the present invention.

FIG. 6 illustrates a change in the size of skyrmions depending on the magnitude of a voltage pulse applied to the microelectrode, based on voltage pulses applied to the top and bottom electrodes of the skyrmion memory device according to an embodiment of the present invention.

Referring to FIG. 6, Image 600 shows a case where a voltage having a magnitude of 0.9 V and a voltage pulse of 200 ms is applied, and Image 610 shows a case where a voltage having a magnitude of 1.0 V and a voltage pulse of 200 ms is applied.

Image 620 shows a case where a voltage having a magnitude of 1.1 V and a voltage pulse of 200 ms is applied, and Image 630 shows a case where a voltage having a magnitude of 1.2 V and a voltage pulse of 200 ms is applied.

In Images 600 to 630, it can be confirmed that the size of skyrmions formed is 1.5 μm to 2 μm, and the number of skyrmions formed increases as the magnitude of the voltage increases.

Therefore, the present invention may provide a skyrmion memory device that can be used as a magnetic non-volatile memory capable of high-speed rewriting, a neuromorphic computing element, a neuromorphic device, and artificial intelligence hardware.

FIGS. 7 to 9c are diagrams for explaining the characteristics of the microelectrode of the skyrmion memory device according to an embodiment of the present invention.

FIG. 7 illustrates thin-film deposition structures related to the characteristics of a VCM electrode, an ECM electrode, and a combined VCM+ECM electrode which are used as microelectrodes according to an embodiment of the present invention.

Referring to FIG. 7, a first thin-film deposition structure 700 is a thin-film deposition structure of a VCM electrode, in which the metal electrode of the microelectrode is formed of Pt, the resistive switching layer is formed of HfOx, and the top electrode is formed of TiN.

In the first thin-film deposition structure 700, in a set state, the metal electrode serves as a negative electrode, and oxygen vacancies 710 form fine filaments in the resistive switching layer. In a reset state, the metal electrode serves as a positive electrode, and the fine filaments based on the oxygen vacancies 710 collapse together with oxygen ions 711.

A second thin-film deposition structure 701 is a thin-film deposition structure of an ECM electrode, in which the metal electrode of the microelectrode is formed of Ag, the resistive switching layer is formed of HfOx, and the top electrode is formed of TiN.

In the second thin-film deposition structure 701, in a set state, the metal electrode serves as a positive electrode, Ag 712 forms fine filaments in the resistive switching layer, and the oxygen vacancies 710 are located around together with oxygen ions 711.

In addition, in the second thin-film deposition structure 701, in a reset state, the metal electrode serves as a negative electrode, and the filaments based on Ag 712 collapse in the resistive switching layer.

A third thin-film deposition structure 702 is a thin-film deposition structure of a composite electrode of VCM and ECM, in which the metal electrode of the microelectrode is formed of Ru, the resistive switching layer is formed of HfOx, and the top electrode is formed of TiN.

In the third thin-film deposition structure 702, in a set state, the metal electrode serves as a positive electrode, Ru 714 forms fine filaments in the resistive switching layer, and the oxygen vacancies 710 also form fine filaments.

In the third thin-film deposition structure 702, in a reset state, the metal electrode serves as a negative electrode, and the filament based on Ru 714 together with the filament based on the oxygen vacancies 710 collapses in the resistive switching layer.

In order for the skyrmion memory device to generate skyrmions in the free layer, a microelectrode capable of increasing current density may be required.

The microelectrode increases current density by delivering high current density through filaments formed in a set state after depositing VCM, ECM, or VCM+ECM electrodes.

Therefore, the microelectrode may increase the current density delivered to the free layer of the skyrmion memory device while ensuring high reliability.

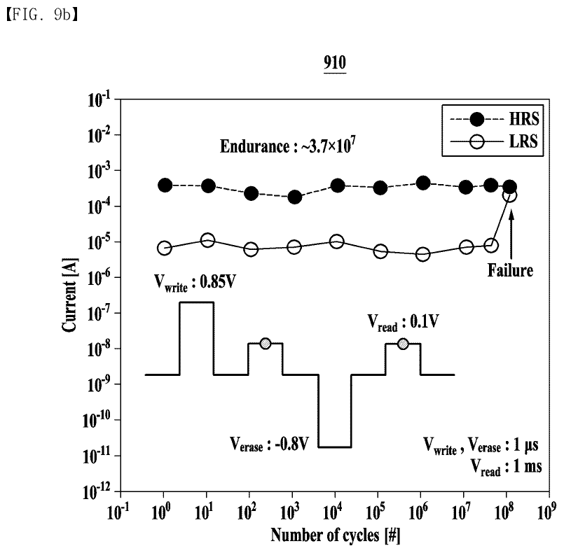

FIGS. 8a to 8c illustrate I-V curves related to the characteristics of a VCM electrode, an ECM electrode, and a combined VCM+ECM electrode used as a microelectrode according to an embodiment of the present invention.

Graph 800 of FIG. 8a illustrates the I-V curve of the VCM electrode, Graph 810 of FIG. 8b illustrates the I-V curve of the ECM electrode, and Graph 820 of FIG. 8c illustrates the I-V curve of the VCM+ECM electrode.

In Graph 800, for the VCM electrode, the forming voltage (Vforming) is −4.38 V, the set voltage (Vset) is −0.59 V, and the reset voltage (Vreset) is 1.40 V.

In Graph 810, for the ECM electrode, the forming voltage (Vforming) is 2.98 V, the set voltage (Vset) is 0.84 V, and the reset voltage (Vreset) is −0.80 V.

In Graph 820, for the VCM+ECM electrode, the forming voltage (Vforming) is 5.15 V, the set voltage (Vset) is 5.10 V, and the reset voltage (Vreset) is −5.00 V.

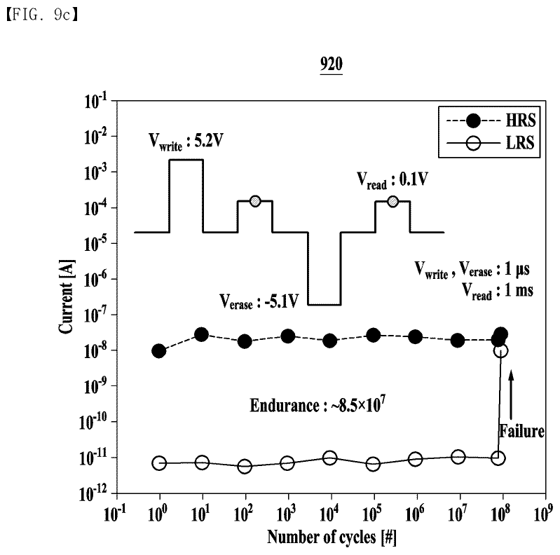

FIGS. 9a to 9c illustrate endurance characteristics related to a VCM electrode, an ECM electrode, and a combined VCM+ECM electrode used as a microelectrode according to an embodiment of the present invention.

Graph 900 of FIG. 9a illustrates the endurance of the VCM electrode, Graph 810 of FIG. 8b illustrates the endurance of the ECM electrode, and Graph 820 of FIG. 8c illustrates the endurance of the VCM+ECM electrode.

The endurance of the VCM electrode in Graph 900 is 7.8×10⁶ or less, the endurance of the ECM electrode in Graph 910 is 3.7×10⁷ or less, and the endurance of the VCM+ECM electrode in Graph 920 is 8.5×10⁷ or less.

Therefore, the present invention can secure high reliability by using a microelectrode formed of ECM, VCM, or a mixture of ECM and VCM and, accordingly, delivering high current density through filaments.

Although the present invention has been described with reference to limited embodiments and drawings, it should be understood by those skilled in the art that various changes and modifications may be made therein. For example, the described techniques may be performed in a different order than the described methods, and/or components of the described systems, structures, devices, circuits, etc., may be combined in a manner that is different from the described method, or appropriate results may be achieved even if replaced by other components or equivalents.

Therefore, other embodiments, other examples, and equivalents to the claims are within the scope of the following claims.

1. A skyrmion memory device, comprising:
a microelectrode for generating one or more skyrmions; and
a magnetic tunnel junction for controlling and detecting a size and number of the generated skyrmions,
wherein the magnetic tunnel junction comprises a seed layer, a synthetic anti-ferromagnetic layer, a bridge layer, a pinned layer, a tunnel barrier layer, an insertion layer, and a free layer,
the microelectrode generates the skyrmions in the free layer when a voltage pulse is applied through a bottom electrode and a top electrode, and
the size and number of the generated skyrmions are controlled based on at least one of a magnitude of the voltage pulse, a thickness of the insertion layer, and a type of material forming the insertion layer.

2. The skyrmion memory device according to claim 1, wherein the magnetic tunnel junction controls a resistance level in a multi-level manner as a Dzyaloshinskii-Moriya Interaction (DMI) and Perpendicular Magnetic Anisotropy (PMA) of the free layer are controlled based on the thickness of the insertion layer, thereby controlling the size and number of the skyrmions.

3. The skyrmion memory device according to claim 1, wherein the magnetic tunnel junction detects multi-bit skyrmions when a plurality of skyrmions are present, and an area of the free layer increases according to the multi-bit skyrmions.

4. The skyrmion memory device according to claim 1, wherein the magnetic tunnel junction secures linearity of potentiation and depression implemented in a multi-level manner as an area of the free layer increases and, accordingly, a resistance level gradually changes.

5. The skyrmion memory device according to claim 1, wherein the insertion layer is formed of one of Ta, W, Pt, Mo, and Ti, and
a thickness of the insertion layer is inversely proportional to the size and number of the generated skyrmions.

6. The skyrmion memory device according to claim 1, wherein the microelectrode is one of an electrochemical metallization memory (ECM) electrode, a valence change memory (VCM) electrode, and a combined ECM and VCM electrode, and is configured to control a density of current applied to the free layer.

7. The skyrmion memory device according to claim 6, wherein the microelectrode comprises a metal electrode and a resistive switching layer,
the resistive switching layer is formed of one of SiOx, MgO, HfOx, AlOx, TiOx, TaOx, GeSe, GeS2, GeTe, and ZnTe, and
the metal electrode is formed of one of Al, TiN, Ti, W, Cu, CuTe, Pt, Ag, and Ru.

8. The skyrmion memory device according to claim 1, wherein the magnetic tunnel junction comprises an additional tunnel barrier layer between the microelectrode and the free layer, and comprises an additional free layer between the insertion layer and the tunnel barrier layer, thereby comprising a double free layer in which the skyrmions are generated.

9. The skyrmion memory device according to claim 1, further comprising:
the bottom electrode located below the magnetic tunnel junction; and
the top electrode located on the microelectrode.

10. A crossbar array circuit using a skyrmion memory device, the skyrmion memory device comprising a top electrode, a bottom electrode, a microelectrode for generating one or more skyrmions, and a magnetic tunnel junction for controlling and detecting a size and number of the generated skyrmions,
wherein the magnetic tunnel junction comprises a seed layer, a synthetic anti-ferromagnetic layer, a bridge layer, a pinned layer, a tunnel barrier layer, an insertion layer, and a free layer,
wherein the microelectrode generates the skyrmions in the free layer when a voltage pulse is applied to the bottom electrode and the top electrode, and the magnetic tunnel junction controls the size and number of the generated skyrmions based on at least one of a magnitude of the voltage pulse, a thickness of the insertion layer, and a type of material forming the insertion layer,
the circuit comprising: an array of a plurality of bit cells, wherein each of the bit cells is formed by connecting a first control signal line to the top electrode and a second control signal line to the bottom electrode of the skyrmion memory device; a selection driver for applying a selection control signal through one of the first control signal line and the second control signal line; and a read and write controller for applying read and write control signals through the other of the first control signal line and the second control signal line.

11. The crossbar array circuit of claim 10, wherein the bit cell has a 2-terminal structure in which the first control signal line is connected to the top electrode and the second control signal line is connected to the bottom electrode.
